(19) United States
(12) Patent Application Publication
(10) Pub. No.: US 2024/0334768 A1
(43) Pub. Date: Oct. 3, 2024

(54) DISPLAY DEVICE

(71) Applicant: Japan Display Inc., Tokyo (JP)

(72) Inventors: Hideyuki TAKAHASHI, Tokyo (JP); Hiroyuki KIMURA, Tokyo (JP); Hiroshi TABATAKE, Tokyo (JP); Tetsuo MORITA, Tokyo (JP)

(73) Assignee: Japan Display Inc., Tokyo (JP)

(21) Appl. No.: 18/597,964

(22) Filed: Mar. 7, 2024

(30) Foreign Application Priority Data
Mar. 29, 2023 (JP) 2023-053369
Jul. 10, 2023 (JP) 2023-112909

(51) Int. Cl. H10K 59/131

(52) U.S. Cl. CPC H10K 59/131

(57) ABSTRACT

According to one embodiment, a display device includes a display area which includes a plurality of subpixels, a plurality of lower electrodes provided in the subpixels, respectively, a plurality of organic layers which cover the lower electrodes, respectively, and emit light based on applied voltage, and a common electrode which covers the organic layers and overlaps the display area. Further, the common electrode has a slit in which at least an end reaches an outer edge of the common electrode.

### CROSS-REFERENCE TO RELATED APPLICATIONS

This application is based upon and claims the benefit of priority from Japanese Patent Applications No. 2023-053369, filed Mar. 29, 2023; and No. 2023-112909, filed Jul. 10, 2023, the entire contents of all of which are incorporated herein by reference.

### FIELD

Embodiments described herein relate generally to a display device.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer. Common voltage is applied to the upper electrode of each display element through lines provided in a display area. These upper electrodes and lines constitute a common electrode which overlaps the display area as a whole.

In some cases, an antenna which transmits and receives radio waves for near field communication (NFC) is incorporated into an electronic device comprising a display device in a state where the antenna overlaps the display device. In this case, eddy current could occur in a common electrode because of a magnetic field generated by the antenna. If the resistance of the common electrode is low, the magnetic field generated by eddy current becomes strong and may be a cause of interruption of communication performed by the antenna.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is a schematic cross-sectional view of the display device along the III-III line of FIG. 2.

FIG. 4 is a schematic plan view showing some elements of the display device.

FIG. 5 is a diagram for explaining the effect of the display device according to the first embodiment.

FIG. 6 is a diagram for explaining the effect of the display device according to the first embodiment.

FIG. 7 is a schematic plan view showing some elements of a display device according to a second embodiment.

FIG. 8 is a schematic plan view showing some elements of a display device according to a third embodiment.

FIG. 9 is a schematic plan view showing some elements of a display device according to a fourth embodiment.

FIG. 10 is a schematic plan view showing some elements of a display device according to a fifth embodiment.

FIG. 11 is a schematic plan view showing some elements of a display device according to a sixth embodiment.

FIG. 12 is a schematic plan view showing another example of the display device according to the sixth embodiment.

FIG. 13 is a schematic plan view showing some elements of a display device according to a seventh embodiment.

FIG. 14 is a schematic plan view showing another example of the display device according to the seventh embodiment.

FIG. 15 is a schematic plan view showing yet another example of the display device according to the seventh embodiment.

FIG. 16 is a schematic plan view showing yet another example of the display device according to the seventh embodiment.

### DETAILED DESCRIPTION

In general, according to one embodiment, a display device comprises a display area which includes a plurality of subpixels, a plurality of lower electrodes provided in the subpixels, respectively, a plurality of organic layers which cover the lower electrodes, respectively, and emit light based on applied voltage, and a common electrode which covers the organic layers and overlaps the display area. Further, the common electrode has a slit in which at least an end reaches an outer edge of the common electrode.

The embodiment can provide a display device which can prevent an effect caused to wireless communication.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. The third direction Z is a normal direction relative to a plane including the first direction X and the second direction Y. When various elements are viewed parallel to the third direction Z, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

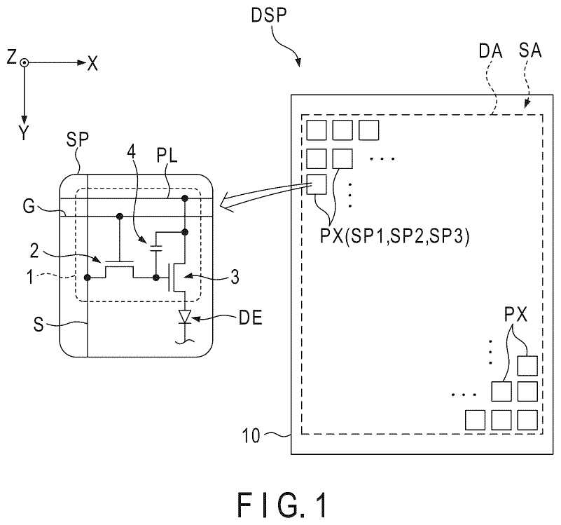

FIG. 1 is a diagram showing a configuration example of a display device DSP according to a first embodiment. The display device DSP comprises an insulating substrate 10. The substrate 10 has a display area DA which displays an image, and a surrounding area SA around the display area DA. The substrate 10 may be glass or a resinous film having flexibility.

In the present embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes a blue subpixel SP1, a green subpixel SP2 and a red subpixel SP3. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. The pixel switch 2 and the drive transistor 3 are, for example, switching elements consisting of a thin-film transistor.

In the display area DA, a plurality of scanning lines G which supply a scanning signal to the pixel circuit 1 of each subpixel SP, a plurality of signal lines S which supply a video signal to the pixel circuit 1 of each subpixel SP and a plurality of power lines PL are provided. In the example of FIG. 1, the scanning lines G and the power lines PL extend in the first direction X, and the signal lines S extend in the second direction Y.

The gate electrode of the pixel switch 2 is connected to the scanning line G. One of the source electrode and drain electrode of the pixel switch 2 is connected to the signal line S. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

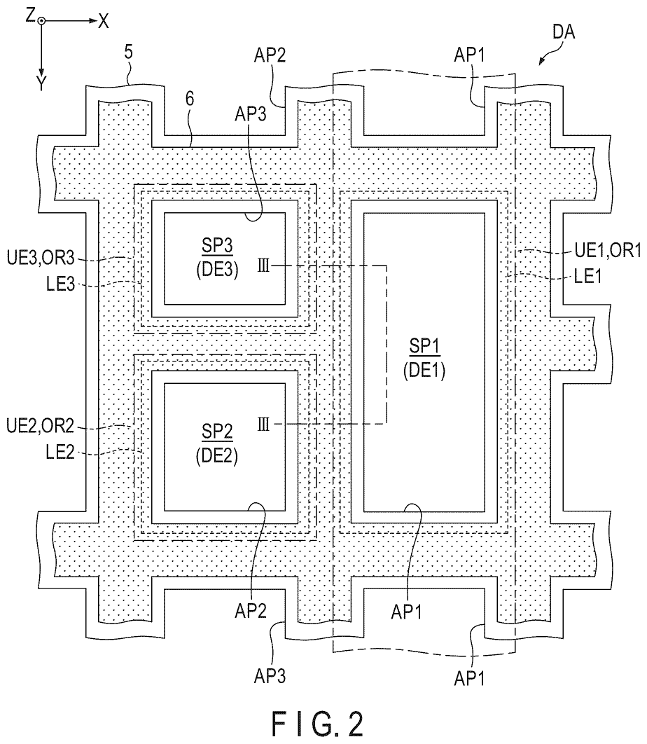

It should be noted that the configuration of the pixel circuit 1 is not limited to the example shown in the figure. For example, the pixel circuit 1 may comprise more thin-film transistors and capacitors. FIG. 2 is a schematic plan view showing an

example of the layout of subpixels SP1, SP2 and SP3. In the example of FIG. 2, each of subpixels SP2 and SP3 is adjacent to subpixel SP1 in the first direction X. Further, subpixels SP2 and SP3 are arranged in the second direction Y.

When subpixels SP1, SP2 and SP3 are provided in line with this layout, in the display area DA, a column in which subpixels SP2 and SP3 are alternately provided in the second direction Y and a column in which a plurality of subpixels SP1 are repeatedly provided in the second direction Y are formed. These columns are alternately arranged in the first direction X. It should be noted that the layout of subpixels SP1, SP2 and SP3 is not limited to the example of FIG. 2.

A rib 5 is provided in the display area DA. The rib 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 surrounds each of these display elements DE1, DE2 and DE3.

A conductive partition 6 is provided on the rib 5. The partition 6 overlaps the rib 5 as a whole and has the same planar shape as the rib 5. In other words, the partition 6 has an aperture in each of subpixels SP1, SP2 and SP3. From another viewpoint, the rib 5 and the partition 6 are provided in the boundaries of subpixels SP1, SP2 and SP3, and have grating shapes as seen in plan view.

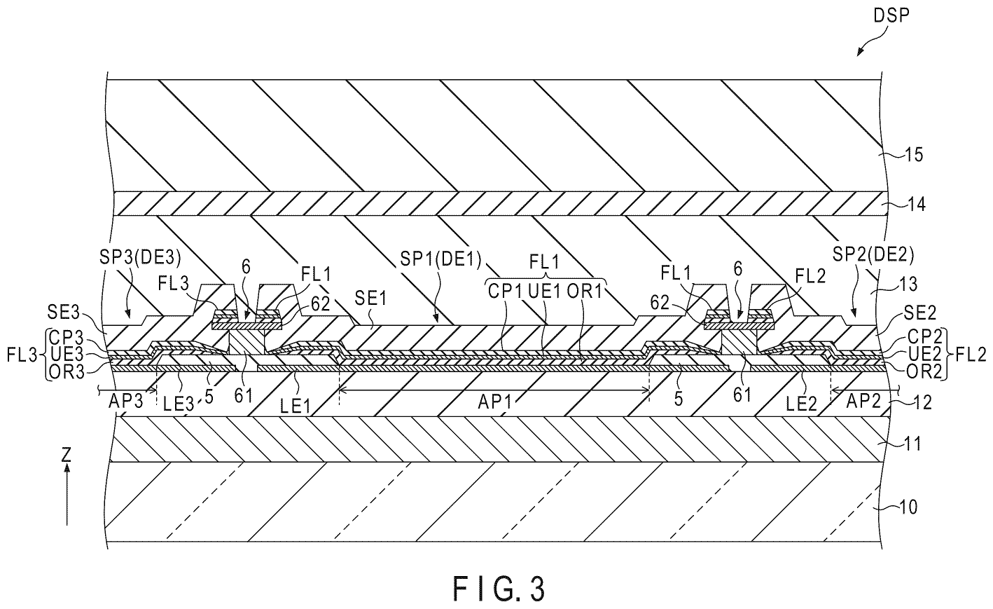

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, scanning line G, signal line S and power line PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portion 61 of the partition 6.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located under the partition 6 (in other words, the portion which constitutes the display element DE1). Similarly, the stacked film FL2 is partly located on the upper portion 62. This portion is spaced apart from, of the stacked film FL2, the portion located under the partition 6 (in other words, the portion which constitutes the display element DE2). Further, the stacked film FL3 is partly located on the upper portion 62. This portion is spaced apart from, of the stacked film FL3, the portion located under the partition 6 (in other words, the portion which constitutes the display element DE3).

Sealing layers SE1, SE2 and SE3 are provided in subpixels SP1, SP2 and SP3, respectively. The sealing layer SE1 continuously covers the stacked film FL1 and the partition 6 around subpixel SP1. The sealing layer SE2 continuously covers the stacked film FL2 and the partition 6 around subpixel SP2. The sealing layer SE3 continuously covers the stacked film FL3 and the partition 6 around subpixel SP3.

In the example of FIG. 3, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The sealing layers SE1, SE2 and SE3 are covered with a resin layer 13. The resin layer 13 is covered with a sealing layer 14. The sealing layer 14 is covered with a resin layer 15. The resin layers 13 and 15 and the sealing layer 14 are continuously provided in at least the entire display area DA and partly extend in the surrounding area SA as well.

A cover member such as a polarizer, a touch panel, a protective film or a cover glass may be further provided above the resin layer 15. This cover member may be attached to the resin layer 15 via, for example, an adhesive layer such as an optical clear adhesive (OCA).

The organic insulating layer 12 is formed of an organic insulating material such as polyimide. Each of the rib 5 and the sealing layers 14, SE1, SE2 and SE3 is formed of an inorganic insulating material such as silicon nitride (SiNx), silicon oxide (Siox), silicon oxynitride (SiON) or aluminum oxide (Al₂O₃). For example, the rib 5 is formed of silicon oxynitride, and each of the sealing layers 14, SE1, SE2 and SE3 is formed of silicon nitride. Each of the resin layers 13 and 15 is formed of, for example, a resinous material (organic insulating material) such as epoxy resin or acrylic resin.

Each of the lower electrodes LE1, LE2 and LE3 has a reflective layer formed of, for example, silver (Ag), and a pair of conductive oxide layers covering the upper and lower surfaces of the reflective layer. Each conductive oxide layer may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

For example, each of the organic layers OR1, OR2 and OR3 comprises a multilayer structure consisting of a hole injection layer, a hole transport layer, an electron blocking layer, a light emitting layer, a hole blocking layer, an electron transport layer and an electron injection layer. Each of the organic layers OR1, OR2 and OR3 may comprise a tandem structure including a plurality of light emitting layers. Each of the cap layers CP1, CP2 and CP3

comprises, for example, a multilayer structure in which a plurality of transparent thin films are stacked. The thin films may include a thin film formed of an inorganic material and a thin film formed of an organic material. These thin films have refractive indices different from each other. For example, the refractive indices of these thin films are different from the refractive indices of the upper electrodes UE1, UE2 and UE3 and the refractive indices of the sealing layers SE1, SE2 and SE3. It should be noted that at least one of the cap layers CP1, CP2 and CP3 may be omitted.

The lower portion 61 of the partition 6 is formed of, for example, aluminum. The lower portion 61 may be formed of an aluminum alloy such as an aluminum-neodymium alloy (AlNd), an aluminum-yttrium alloy (AlY) or an aluminum-silicon alloy (AlSi), or may comprise a multilayer structure consisting of an aluminum layer and an aluminum alloy layer. Further, the lower portion 61 may have a bottom layer formed of a metal material different from aluminum and an aluminum alloy under the aluminum layer or the aluminum alloy layer. For the metal material forming the bottom layer, for example, molybdenum (Mo), titanium nitride (TiN), a molybdenum-tungsten alloy (MoW) or a molybdenum-niobium alloy (MoNb) may be used.

For example, the upper portion 62 of the partition 6 comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy may be used. For the conductive oxide forming the upper layer, for example, ITO or IZO may be used. It should be noted that the upper portion 62 may comprise a single-layer structure of a metal material. The upper portion 62 may further include a layer formed of an insulating material.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively, based on the video signals of the signal lines S.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

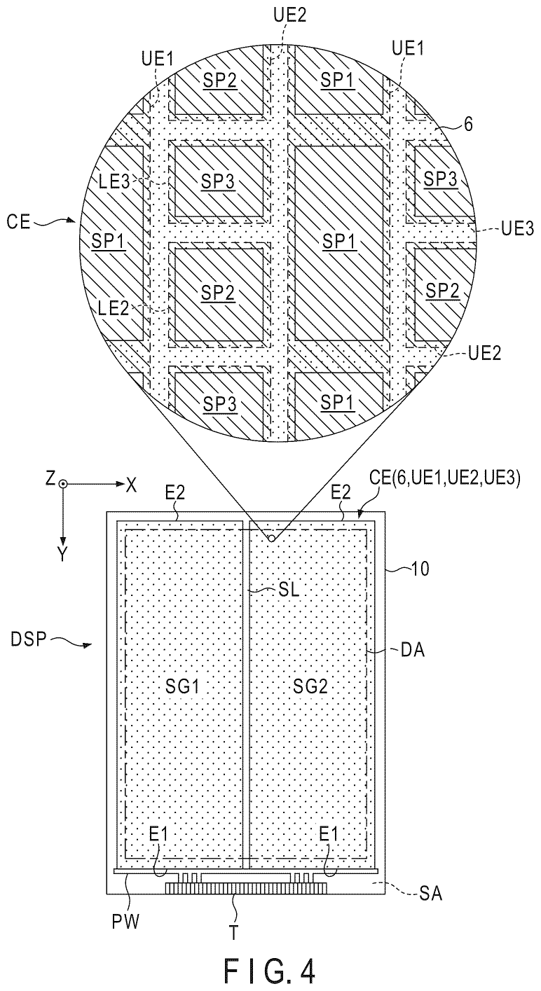

FIG. 4 is a schematic plan view showing some elements of the display device DSP. The partition 6 and the upper electrodes UE1, UE2 and UE3 constitute a common electrode CE which applies common voltage to the display elements DE1, DE2 and DE3. As shown in the enlarged view of FIG. 4, the upper electrodes UE1, UE2 and UE3 are provided in subpixels SP1, SP2 and SP3 included in the display area DA, and further, the partition 6 is provided in the gaps of the upper electrodes UE1, UE2 and UE3. Thus, the common electrode CE overlaps the display area DA as a whole.

A terminal portion T including a plurality of pads is provided in the surrounding area SA. A flexible printed circuit (FPC) is connected to the terminal portion T via, for example, a conductive adhesive material. Voltage and signals necessary for image display are supplied through these flexible printed circuit and terminal portion T.

Further, a power supply line PW is provided in the surrounding area SA. Common voltage is applied to the power supply line PW from the terminal portion T. In the example of FIG. 4, the power supply line PW extends in the first direction X between the terminal portion T and the display area DA.

The common electrode CE has a slit SL in which at least an end reaches the outer edge of the common electrode CE (the outline in plan view). In the example of FIG. 4, both ends of the slit SL reach the outer edge of the common electrode CE. By this configuration, the common electrode CE is divided into two segments SG1 and SG2 which are spaced apart from each other via the slit SL.

In the example of FIG. 4, the slit SL extends in the second direction Y. From another viewpoint, the slit SL extends parallel to the signal lines S shown in FIG. 1. For example, the slit SL is located in the center of the common electrode CE in the first direction X (in other words, the center of the display area DA in the first direction X). In this case, the widths of the segments SG1 and SG2 in the first direction X are equal to each other.

Each of the segments SG1 and SG2 has a first end portion E1 and a second end portion E2 in the second direction Y (the extension direction of the slit SL). The first end portion E1 of each of the segments SG1 and SG2 is connected to the power supply line PW. Thus, the segments SG1 and SG2 are electrically connected to each other via the power supply line PW. The second end portions E2 of the segments SG1 and SG2 are spaced apart from each other via the slit SL and are not connected by a conductive member such as the power supply line PW.

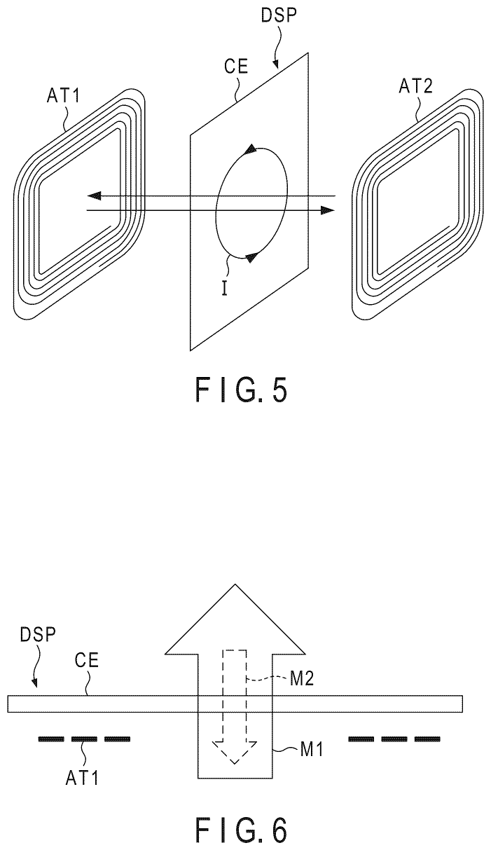

FIG. 5 and FIG. 6 are diagrams for explaining the effect of the display device DSP according to the embodiment. An electronic device on which the display device DSP is mounted may comprise an antenna AT1 for near field communication (NFC). The antenna AT1 is provided so as to, for example, face the rear side of the display device DSP (in other words, the lower surface of the substrate 10 shown in FIG. 3) and wirelessly communicates with the antenna AT2 of another electronic device through the display device DSP.

At the time of wireless communication between the antennas AT1 and AT2, eddy current I is generated in the common electrode CE by magnetic field M1 formed by the antenna AT1. By eddy current I, magnetic field M2 which negates magnetic field M1 is formed, and the signal strength is attenuated. Thus, when wireless communication is performed via the display device DSP, the communication sensitivity could be decreased. In particular, when the partition 6 mainly formed of a metal material and having a grating shape is formed in the entire display area DA, the resistance of the common electrode CE is low. Thus, a large eddy current I occurs, thereby generating a strong magnetic field M2. Thus, the communication sensitivity is easily decreased.

To the contrary, in the embodiment, the common electrode CE is divided into a plurality of segments SG1 and SG2 by the slit SL. In this case, a large eddy current is not easily generated in the common electrode CE. Thus, the decrease in communication sensitivity can be prevented. Eddy current could be generated in each of the segments SG1 and SG2. However, the effect caused to communication sensitivity by this eddy current is tiny compared to eddy current I generated in the entire part of a common electrode CE which is not divided.

The configuration disclosed in the present embodiment could be modified in various ways. The second to eighth embodiments described below disclose other examples of a configuration which could be applied to the common electrode CE. The configurations and effects which are not particularly referred to in these embodiments are the same as those of the first embodiment.

### Second Embodiment

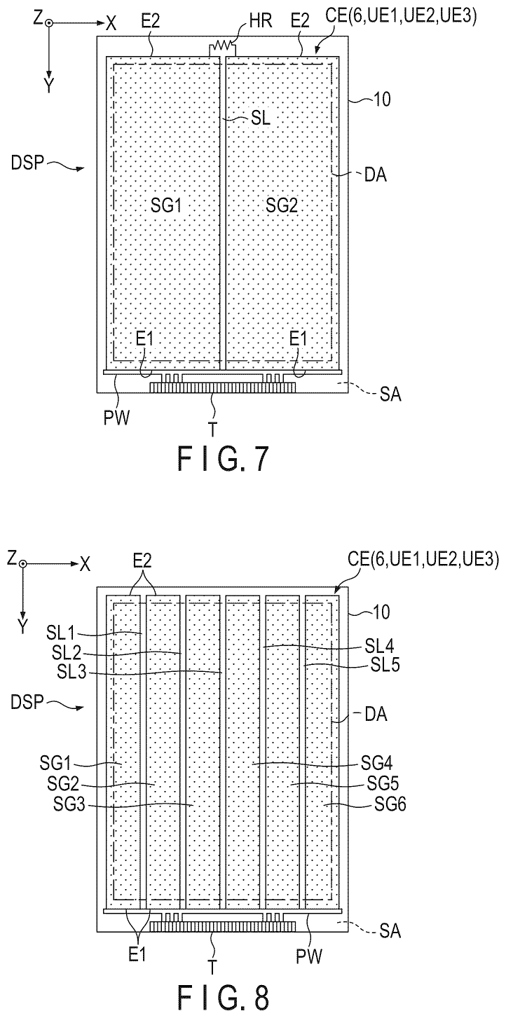

FIG. 7 is a schematic plan view showing some elements of a display device DSP according to the second embodiment. In the example of this figure, segments SG1 and SG2 are connected to each other by a high-resistive portion HR.

The high-resistive portion HR has a resistance which is higher than that of a common electrode CE. The high-resistive portion HR is provided in a surrounding area SA and connects the second end portions E2 of the segments SG1 and SG2 to each other. The first end portions E1 of the segments SG1 and SG2 may be connected to each other by a similar high-resistive portion.

Even in a case where an antenna AT1 is used so as to overlap the display device DSP of the embodiment as shown in FIG. 5, since the resistance of the high-resistive portion HR is higher than that of the common electrode CE, eddy current through the high-resistive portion HR is not easily generated. Thus, in a manner similar to that of the first embodiment, the decrease in communication sensitivity can be prevented.

### Third Embodiment

FIG. 8 is a schematic plan view showing some elements of a display device DSP according to the third embodiment. In the example of this figure, a common electrode CE is divided into six segments SG1, SG2, SG3, SG4, SG5 and SG6 by five slits SL1, SL2, SL3, SL4 and SL5. All of the both ends of the slits SL1 to SL5 reach the outer edge of the common electrode CE.

All of the slits SL1 to SL5 extend parallel to a second direction Y. The segments SG1 to SG6 have a shape which is elongated in the second direction Y and are arranged in a first direction X. In FIG. 8, the widths of the segments SG1 to SG6 (the intervals of the slits SL1 to SL5) are equal to each other. However, the configuration is not limited to this example.

All of the first end portions E1 of the segments SG1 to SG6 are connected to a power supply line PW. In the example of FIG. 8, the second end portions E2 of the segments SG1 to SG6 are spaced apart from each other. As another example, the second end portions E2 of adjacent two segments of the segments SG1 to SG6 may be connected to each other by a high-resistive portion HR which is similar to that of the second embodiment.

### Fourth Embodiment

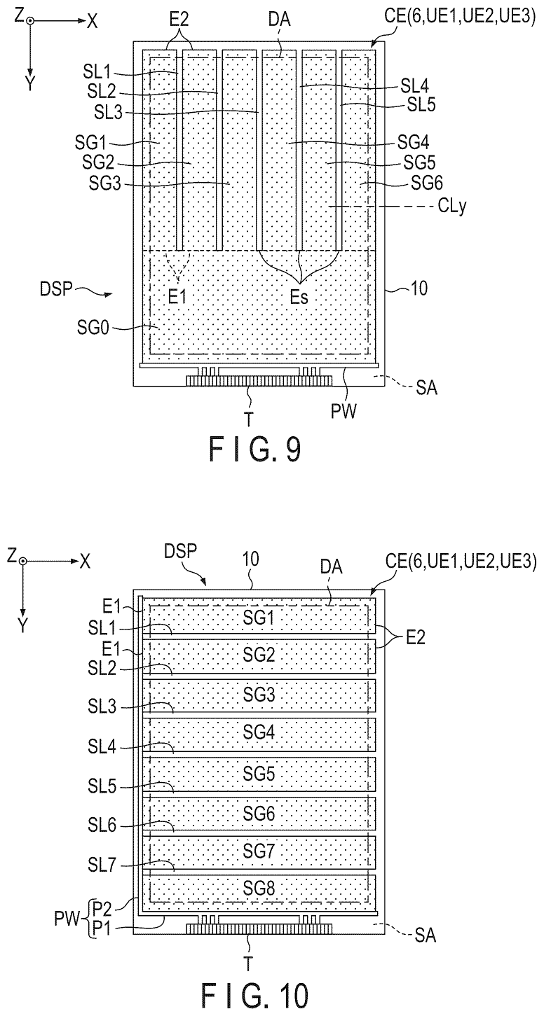

FIG. 9 is a schematic plan view showing some elements of a display device DSP according to the fourth embodiment. In the example of this figure, in a manner similar to that of the third embodiment, five slits SL1 to SL5 are provided in a common electrode CE such that the common electrode CE is divided into six segments SG1 to SG6.

It should be noted that, in the example of FIG. 9, end portions Es of the slits SL1 to SL5 on the power supply line PW side do not reach the outer edge of the common electrode CE. By this configuration, a segment SG0 having a width greater than the widths of the segments SG1 to SG6 in a first direction X is formed between the segments SG1 to SG6 and the power supply line PW.

An end of the segment SG0 in a second direction Y is connected to the first end portions E1 of the segments SG1 to SG6. The other end of the segment SG0 in the second direction Y is connected to the power supply line PW.

In the example of FIG. 9, the positions of the end portions Es of the slits SL1 to SL5 in the second direction Y are aligned with each other. Further, these end portions Es are located on the power supply line PW side relative to the center CLy of the common electrode CE in the second direction Y. The configuration is not limited to this example. The positions of the end portions Es in the second direction Y may be misaligned with each other. The end portions Es may be located on the second end portion E2 side relative to the center CLy.

In the example of FIG. 9, the second end portions E2 of the segments SG1 to SG6 are spaced apart from each other. As another example, the second end portions E2 of adjacent two segments of the segments SG1 to SG6 may be connected to each other by a high-resistive portion HR which is similar to that of the second embodiment.

Even when the slits SL (SL1 to SL5) do not completely divide the common electrode CE as in the case of this embodiment, it is possible to obtain an effect of preventing the eddy current described above and improving the communication sensitivity of near field communication.

### Fifth Embodiment

FIG. 10 is a schematic plan view showing some elements of a display device DSP according to the fifth embodiment. In the example of this figure, a common electrode CE is divided into eight segments SG1, SG2, SG3, SG4, SG5, SG6, SG7 and SG8 by seven slits SL1, SL2, SL3, SL4, SL5, SL6 and SL7.

All of the slits SL1 to SL7 extend parallel to a first direction X. From another viewpoint, the slits SL1 to SL7 extend parallel to the scanning lines G shown in FIG. 1. All of the both ends of the slits SL1 to SL7 in the first direction X reach the outer edge of the common electrode CE.

The segments SG1 to SG8 have a shape which is elongated in the first direction X and are arranged in a second direction Y. In FIG. 10, the widths of the segments SG1 to SG8 (the intervals of the slits SL1 to SL7) in the second direction Y are equal to each other. However, the configuration is not limited to this example.

A power supply line PW has a first portion P1 extending in the first direction X and a second portion P2 extending in the second direction Y. The first portion P1 is located between a display area DA and a terminal portion T. The second portion P2 is provided along the left side of the display area DA in the figure and is connected to the first portion P1.

Each of the segments SG1 to SG8 has a first end portion E1 and a second end portion E2 in the first direction X (the extension direction of the slits SL1 to SL7). The first end portion E1 of each of the segments SG1 to SG8 is connected to the second portion P2. In the example of FIG. 10, the second end portions E2 of the segments SG1 to SG8 are spaced apart from each other. As another example, the second end portions E2 of adjacent two segments of the segments SG1 to SG8 may be connected to each other by a high-resistive portion HR which is similar to that of the second embodiment.

Even when the slits SL (SL1 to SL7) extend parallel to the first direction X as in the case of this embodiment, it is possible to obtain an effect of preventing the eddy current described above and improving the communication sensitivity of near field communication.

### Sixth Embodiment

FIG. 11 is a schematic plan view showing some elements of a display device DSP according to the sixth embodiment. In this embodiment, a display area DA and a common electrode CE are circular.

The common electrode CE is divided into eight segments SG1, SG2, SG3, SG4, SG5, SG6, SG7 and SG8 by seven slits SL1, SL2, SL3, SL4, SL5, SL6 and SL7.

All of the slits SL1 to SL7 extend parallel to a second direction Y. All of the both ends of the slits SL1 to SL7 in the second direction Y reach the outer edge of the common electrode CE. The segments SG1 to SG8 have a shape which is elongated in the second direction Y and are arranged in a first direction X. In FIG. 11, the intervals of the slits SL1 to SL7 are equal to each other. However, the configuration is not limited to this example.

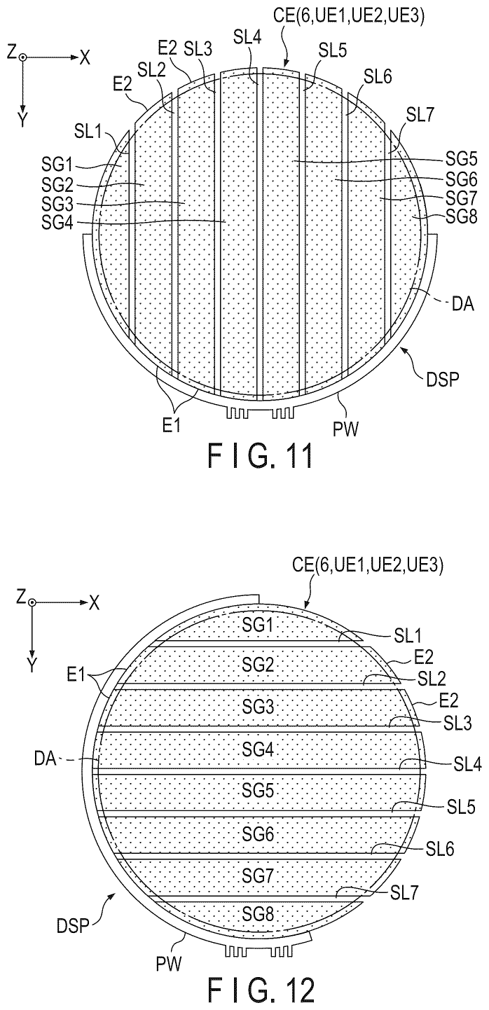

FIG. 12 is a schematic plan view showing another example of the display device DSP according to the embodiment. In the example of this figure, the slits SL1 to SL7 extend parallel to the first direction X. All of the both ends of the slits SL1 to SL7 in the first direction X reach the outer edge of the common electrode CE. The segments SG1 to SG8 have a shape which is elongated in the first direction X and are arranged in the second direction Y. In FIG. 12, the intervals of the slits SL1 to SL7 are equal to each other. However, the configuration is not limited to this example.

In both of the examples of FIG. 11 and FIG. 12, a power supply line PW has a planar shape which is arcuate along the display area DA. The first end portion E1 of each of the segments SG1 to SG8 is connected to the power supply line PW. In the examples of FIG. 11 and FIG. 12, the second end portions E2 of the segments SG1 to SG8 are spaced apart from each other. As another example, the second end portions E2 of adjacent two segments of the segments SG1 to SG8 may be connected to each other by a high-resistive portion HR which is similar to that of the second embodiment.

In the examples of FIG. 11 and FIG. 12, in a manner similar to that of the fourth embodiment, the end portions of the slits SL1 to SL7 on the power supply line PW side may not reach the outer edge of the common electrode CE.

### Seventh Embodiment

In the examples of FIG. 4 and FIG. 7 to FIG. 12, the segments of the common electrode CE have the same width in the arrangement direction of these segments (in other words, a direction orthogonal to the extension direction of the slits). The seventh embodiment exemplarily shows a configuration in which the widths of these segments are different from each other. The configuration disclosed in each of the embodiments described above can be also appropriately applied to this embodiment.

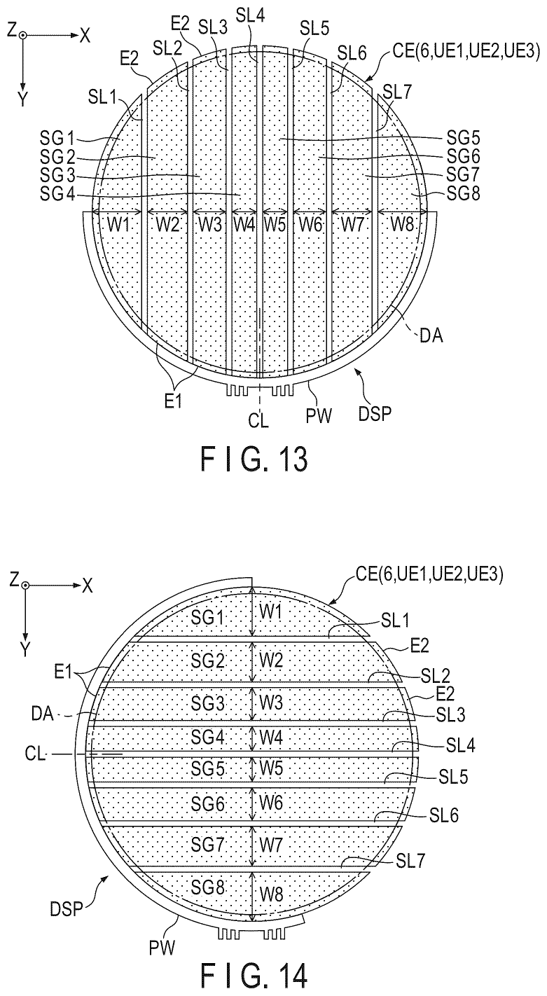

FIG. 13 is a schematic plan view showing some elements of a display device DSP according to the seventh embodiment. In the example of this figure, a common electrode CE is divided into segments SG1 to SG8 arranged in a first direction X by slits SL1 to SL7 extending parallel to a second direction Y. In this case, the second direction Y corresponds to the extension direction of the slits SL1 to SL7, and the first direction X corresponds to the arrangement direction of the segments SG1 to G8.

In the example of FIG. 13, in a manner similar to that of the sixth embodiment, a display area DA and the common electrode CE are circular. In other words, the common electrode CE has a planar shape in which the width in the extension direction of the slits SL1 to SL7 decreases with increasing distance from the center CL in the arrangement direction of the segments SG1 to SG8. A similar configuration is applied to the planar shape of the display area DA. It should be noted that this configuration of the display area DA and the common electrode CE could be realized even in the case of other planar shapes such as an oval.

In the example of FIG. 13, the segments SG1 and SG8 are the farthest from the center CL, and the segments SG4 and SG5 are the closest to the center CL. For example, the center CL is located between the segments SG4 and SG5 and overlaps the slit SL4.

The segments SG1 to SG8 have widths W1 to W8, respectively, in the first direction X. These widths W1 to W8 correspond to, for example, the maximum widths of the segments SG1 to SG8 in the first direction X.

Here, the numbers of pixels PX overlapping the segments SG1 to SG8 are defined as the numbers Pn1 to Pn8 of overlapping pixels, respectively. If each of the display area DA and the common electrode CE has the planar shape shown in FIG. 13, and further, widths W1 to W8 are equal to each other, the numbers Pn1 to Pn8 of overlapping pixels are nonuniform. More specifically, the numbers Pn4 and Pn5 of overlapping pixels are the greatest. The numbers Pn3 and Pn6 of overlapping pixels are the second greatest. The numbers Pn2 and Pn7 of overlapping pixels are the third greatest. The numbers Pn1 and Pn8 of overlapping pixels are the least.

The common voltage of the segments SG1 to SG8 tend to decrease as the number of overlapping pixels increases. When the common voltage decreases, the luminance of subpixels SP1, SP2 and SP3 decreases. Thus, an undesired luminance gradient based on the number of overlapping pixels could be generated in the display area DA.

This luminance gradient can be prevented by differentiating at least some of widths W1 to W8 from each other so as to reduce the difference in the numbers Pn1 to Pn8 of overlapping pixels. Specifically, when a first segment (one of the segments SG1 to SG8) which is spaced apart from the center CL is compared with a second segment (another one of the segments SG1 to SG8) which is closer to the center CL than the first segment, the width of the first segment should be preferably greater than that of the second segment. By this configuration, the difference in the number of overlapping pixels between the first segment and the second segment is reduced. As a result, the difference in the luminances of areas corresponding to these segments is also reduced.

In the example of FIG. 13, widths W1 and W8 are the greatest. Widths W2 and W7 are the second greatest. Widths W3 and W6 are the third greatest. Widths W4 and W5 are the least. By this configuration, the difference in the numbers Pn1 to Pn8 of overlapping pixels is reduced as a whole.

Widths W1 to W8 should be preferably determined such that the difference in the number of overlapping pixels between adjacent two segments of the segments SG1 to SG8 is within 10%. In addition, widths W1 to W8 should be preferably determined such that the difference between the number of overlapping pixels in the segment having the greatest area among the segments SG1 to SG8 and the number of overlapping pixels in the segment having the least area is within 30%. Here, the phrase “the difference in the number of overlapping pixels is within XX %” means that the difference in the number of overlapping pixels is included in the range of −XX % to +XX % of the less number of overlapping pixels of the two numbers of overlapping pixels.

The resistances of the segments SG1 to SG8 change based on the shapes of the segments SG1 to SG8, the form of connection to a power supply line PW, etc. These resistances could also cause common voltage to differ in the segments SG1 to SG8. Therefore, widths W1 to W8 may be determined in consideration of the resistances of the segments SG1 to SG8 in addition to the number of overlapping pixels.

Specifically, the decrease ΔV in the common voltage in a segment is proportional to the product (Pn×R) of the number Pn of overlapping pixels and resistance R of the segment. Thus, widths W1 to W8 could be determined such that the products (Pn×R) with respect to the respective segments SG1 to SG8 are considered to be substantially equal to each other. It should be noted that the phrase “substantially equal to each other” includes a case where the target values to be compared with each other have a difference of, for example, several percent, in addition to a case where the values are coincident with each other.

FIG. 14 is a schematic plan view showing another example of the display device DSP according to the embodiment. In this figure, in a manner similar to that of FIG. 13, the display area DA and the common electrode CE are circular. However, the common electrode CE is divided into segments SG1 to SG8 arranged in the second direction Y by slits SL1 to SL7 extending parallel to the first direction X. In this case, the first direction X corresponds to the extension direction of the slits SL1 to SL7, and the second direction Y corresponds to the arrangement direction of the segments SG1 to G8. In this configuration, in a manner similar to that of the example of FIG. 13, the difference in the luminance of the display area DA can be made uniform by adjusting widths W1 to W8 of the segments SG1 to SG8.

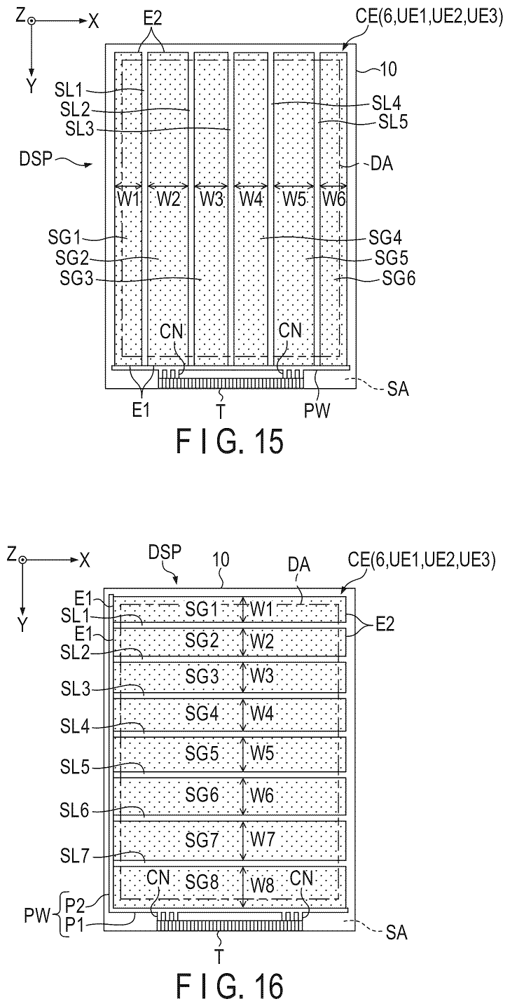

FIG. 15 is a schematic plan view showing yet another example of the display device DSP according to the embodiment. In this figure, in a manner similar to that of the third embodiment (FIG. 8), the planar shapes of the display area DA and the common electrode CE are rectangular. Further, the common electrode CE is divided into segments SG1 to SG6 arranged in the first direction X by slits SL1 to SL5 extending parallel to the second direction Y.

A terminal portion T provided in a surrounding area SA includes a terminal for applying common voltage to the display device DSP. The power supply line PW is connected to the terminal portion T including the terminal via connection portions CN. In the example of FIG. 15, two connection portions CN are provided near the segments SG2 and SG5, respectively.

The common voltages of the segments SG1 to SG6 differ depending on the locational relationship with the connection portions CN. Specifically, the common voltage of a segment which is distant from the connection portions CN could be decreased compared to the common voltage of a segment which is close to the connection portions CN.

The luminance gradient which could be generated by this decrease in common voltage can be prevented by differentiating at least some of widths W1 to W6 of the segments SG1 to SG6 from each other. Specifically, when a first segment having a long distance from the connection portions CN along the power supply line PW is compared with a second segment having a shorter distance from the connection portions CN along the power supply line PW than the first segment, the width of the first segment should be preferably less than that of the second segment. From another view point, the number of overlapping pixels in the first segment should be preferably less than that in the second segment. By this configuration, the decrease in the voltage of the first segment is prevented, and further, the difference in the luminances of areas corresponding to the first segment and the second segment is also reduced.

In the example of FIG. 15, widths W2 and W5 of the segments SG2 and SG5 close to the connection portions CN are the greatest. Widths W1 and W6 of the segments SG1 and SG6 located at the both ends of the display area DA are the least. Widths W3 and W4 of the segments SG3 and SG4 located between two connection portions CN in the first direction X are greater than widths W1 and W6 and less than widths W2 and W5.

FIG. 16 is a schematic plan view showing yet another example of the display device DSP according to the embodiment. In this figure, in a manner similar to that of FIG. 15, the display area DA and the common electrode CE are rectangular. However, the common electrode CE is divided into segments SG1 to SG8 arranged in the second direction Y by slits SL1 to SL7 extending parallel to the first direction X. In this case, the first direction X corresponds to the extension direction of the slits SL1 to SL7, and the second direction Y corresponds to the arrangement direction of the segments SG1 to G8.

In a manner similar to that of the fifth embodiment (FIG. 10), the power supply line PW has a first portion P1 extending in the first direction X and a second portion P2 extending in the second direction Y. The first portion P1 is connected to the connection portions CN. The second portion P2 is connected to the first end portions E1 of the segments SG1 to SG8.

In this configuration, the segment SG1 is the farthest from the connection portions CN along the power supply line PW, and the segment SG8 is the closest to the connection portions CN along the power supply line PW. Accordingly, in the example of FIG. 16, the slits SL1 to SL7 are provided such that widths W1 to W8 of the segments SG1 to SG8 increase in order.

The configurations in which the widths of the segments are differentiated based on the distance from the connection portions CN as explained with reference to FIG. 15 and FIG. 16 can be also applied to the examples of FIG. 13 and FIG. 14.

Other than the configurations of FIG. 13 to FIG. 16 exemplarily shown in the embodiment, the widths of the segments of the common electrode CE may be differentiated from each other in various ways. All of the segments provided in the common electrode CE may not necessarily have a width which is different from that of an adjacent segment. When at least two of a plurality of segments have different widths, an effect of preventing the luminance gradient described above can be obtained.

In the examples of FIG. 4 and FIG. 7, one slit SL is provided in the common electrode CE. In the examples of FIG. 8, FIG. 9 and FIG. 15, five slits SL1 to SL5 are provided in the common electrode CE. In the examples of FIG. 10 to FIG. 14 and FIG. 16, seven slits SL1 to SL7 are provided in the common electrode CE. However, the number of slits provided in the common electrode CE is not limited to these examples and may be two to four, six, or eight or greater. In addition, the shapes of the slits and segments could be modified in various ways.

All of the display devices that can be implemented by a person of ordinary skill in the art through arbitrary design changes to the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
a display area which includes a plurality of subpixels;
a plurality of lower electrodes provided in the subpixels, respectively;
a plurality of organic layers which cover the lower electrodes, respectively, and emit light based on applied voltage; and
a common electrode which covers the organic layers and overlaps the display area, wherein
the common electrode has a slit in which at least an end reaches an outer edge of the common electrode.

2. The display device of claim 1, wherein
both ends of the slit reach the outer edge of the common electrode.

3. The display device of claim 1, wherein
an end of the slit reaches the outer edge of the common electrode, and the other end does not reach the outer edge.

4. The display device of claim 2, wherein
the common electrode has a plurality of segments which are divided by the slit, and
the segments are electrically connected to each other.

5. The display device of claim 4, further comprising a power supply line provided in a surrounding area around the display area, wherein
each of the segments has a first end portion and a second end portion in an extension direction of the slit, and
the first end portion of each of the segments is connected to the power supply line.

6. The display device of claim 4, further comprising a high-resistive portion which has a resistance higher than the segments, is provided in a surrounding area around the display area and connects the segments to each other.

7. The display device of claim 4, wherein
the segments are arranged in an arrangement direction intersecting with an extension direction of the slit, and
at least two of the segments have widths which are different from each other in the arrangement direction.

8. The display device of claim 7, wherein
each of the display area and the common electrode has a planar shape in which a width in the extension direction decreases with increasing distance from a center in the arrangement direction,
the segments include a first segment and a second segment which is closer to the center than the first segment, and
a width of the first segment in the arrangement direction is greater than a width of the second segment in the arrangement direction.

9. The display device of claim 8, wherein
the planar shape of each of the display area and the common electrode is circular.

10. The display device of claim 7, further comprising:
a power supply line provided in a surrounding area around the display area and connected to each of the segments;
a terminal portion including a terminal for applying common voltage; and
a connection portion which connects the terminal portion and the power supply line, wherein
the segments include a first segment and a second segment having a shorter distance from the connection portion along the power supply line than the first segment, and
a width of the first segment in the arrangement direction is less than a width of the second segment in the arrangement direction.

11. The display device of claim 7, wherein
a difference between a number of pixels overlapping one of adjacent two segments of the plurality of segments and a number of pixels overlapping the other segment is within 10%.

12. The display device of claim 7, wherein
a difference between a number of pixels overlapping a segment having a greatest area among the plurality of segments and a number of pixels overlapping a segment having a least area among the plurality of segments is within 30%.

13. The display device of claim 1, further comprising:
a plurality of pixel circuits connected to the lower electrodes, respectively;
a plurality of scanning lines which supply a scanning signal to the pixel circuits; and
a plurality of signal lines which supply a video signal to the pixel circuits, wherein
the slit extends parallel to the signal lines.

14. The display device of claim 1, further comprising:
a plurality of pixel circuits connected to the lower electrodes, respectively;
a plurality of scanning lines which supply a scanning signal to the pixel circuits; and
a plurality of signal lines which supply a video signal to the pixel circuits, wherein
the slit extends parallel to the scanning lines.

15. The display device of claim 1, wherein
the common electrode includes:
a conductive partition provided in boundaries of the subpixels; and
a plurality of upper electrodes which cover the organic layers, respectively, and are in contact with the partition.

16. The display device of claim 15, wherein
the partition includes:
a conductive lower portion; and
an upper portion provided on the lower portion and protruding from a side surface of the lower portion, and
the upper electrodes are in contact with the side surface of the lower portion.
